(19) United States
(12) Patent Application Publication
(10) Pub. No.: US 2013/0142991 A1
(43) Pub. Date: Jun. 6, 2013

(54) COATED ARTICLE AND METHOD FOR MAKING SAME

(71) Applicants: DA-HUA CAO, Shenzhen City (CN); XU LIU, Shenzhen City (CN)

(72) Inventors: DA-HUA CAO, Shenzhen City (CN); XU LIU, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/474,834

(22) Filed: May 18, 2012

(30) Foreign Application Priority Data
Dec. 1, 2011 (CN) 201110392854.5

(51) Int. Cl. B32B 3/24; C23C 14/35; C23C 14/58

(52) U.S. Cl. 428/138; 216/41

(57) ABSTRACT

The coated article includes a substrate having a first color layer and a second color layer formed thereon, and in that order. The first color layer is made of a first metallic material. The second color layer is made of a second metallic material. The first and second color layers have different colors. The second color layer has openings, thereby the first color layer partially exposed out of the second color layer by the openings. A method for making the coated article is also described.

### BACKGROUND

1. Technical Field

The present disclosure generally relates to coated articles and a method for manufacturing the coated articles, particularly to coated articles having two different colored regions and a method for making the coated articles.

2. Description of Related Art

Films made by physical vapor deposition (hereinafter referred to as “PVD films”) are often used on articles, such as housings of electronic devices. A technique for creating an article coated with PVD films having two different colored regions includes masking different portions of a substrate with masking material and forming a first film having a first color by performing a first PVD process on unmasked portions of the substrate. Then, the masking material is removed and the first film is masked by the masking material. A second film having a second color is formed on portions of the substrate uncovered by the first film by performing a second PVD process. Then, the masking material masking the first film is removed. However, such technique is complicated because it involves two masking steps, two PVD processes, and two removing steps. Moreover, two masking steps make it difficult to ensure a high locating accuracy for the masking material.

Therefore, there is room for improvement within the art.

### BRIEF DESCRIPTION OF THE DRAWINGS

Many aspects of the disclosure can be better understood with reference to the following figures. The components in the figures are not necessarily drawn to scale, the emphasis instead being placed upon clearly illustrating the principles of the disclosure.

FIG. 1 is a cross-sectional view of an exemplary embodiment of the present coated article.

FIG. 2 is a cross-sectional view of a second exemplary embodiment of the present coated article.

### DETAILED DESCRIPTION

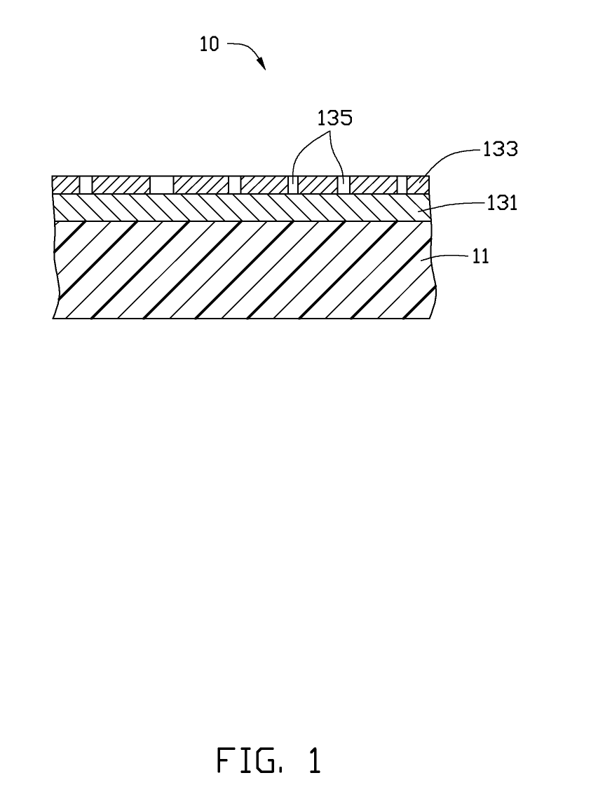

FIG. 1 shows an exemplary embodiment of a coated article 10. The coated article 10 includes a substrate 11, a first color layer 131 directly formed on the substrate 11, and a second color layer 133 directly formed on the first color layer 131. The coated article 10 may be a housing of mobile phone, personal digital apparatus, notebook computer, portable music player, GPS navigator, or digital camera. As used in this disclosure, “directly” means a surface of one layer is in contact with a surface of the other layer. The first color layer 131 and the second color layer 133 have different colors from each other. The second color layer 133 has a plurality of openings 135. The openings 135 may cooperatively form a pattern. The first color layer 131 is partially exposed out of the second color layer 133 by the openings 135, thereby providing two different colored regions on the coated article 10.

The substrate 11 may be made of metal, such as stainless steel, titanium alloy, magnesium alloy, or aluminum alloy. The substrate 11 may also be made of plastic. In the exemplary embodiment, the substrate 11 is made of stainless steel.

The first color layer 131 is made of a metallic material having a first color. The metallic material for the first color layer 131 may be selected from the group consisting of chromium carbide, chromium nitride, and chromium oxynitride. In the case of chromium carbide and chromium nitride, the first color layer 131 will appear silver. In the case of chromium oxynitride, the first color layer 131 will appear blue. The thickness of the first color layer 131 may be about 0.5 μm to about 1.2 μm.

The second color layer 133 is made of a metallic material having a second color which is different from the first color. The metallic material for the second color layer 133 may be selected from the group consisting of titanium carbide, titanium nitride, and titanium carbonitride. In the case of titanium carbide, the second color layer 133 will appear black. In the case of titanium nitride, the second color layer 133 will appear golden. In the case of titanium carbonitride, the second color layer 133 will appear rose or brown. The thickness of the second color layer 133 may be about 0.4 μm to about 0.8 μm.

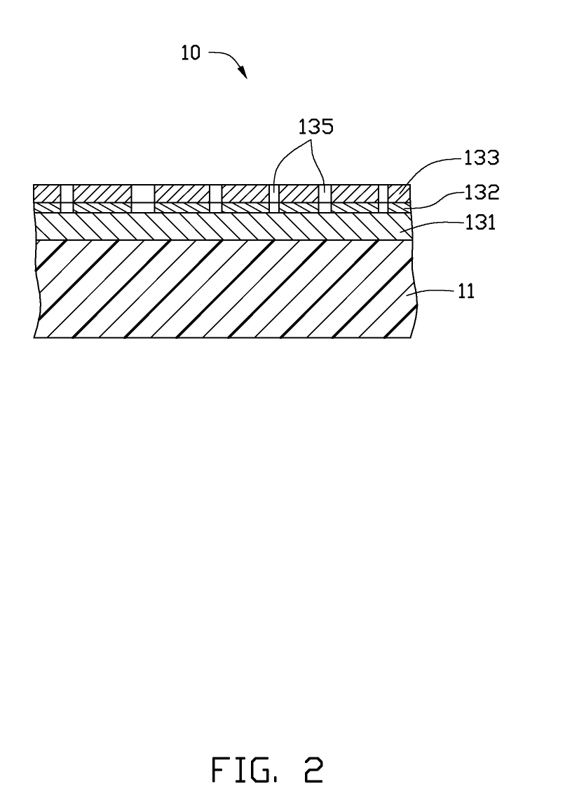

Referring to FIG. 2, in a second exemplary embodiment, to reduce the internal stress between the first color layer 131 and the second color layer 133 and improve the adhesion of the second color layer 133, the coated article 10 may further include transition layer 132 sandwiched between the first color layer 131 and the second color layer 133. The second color layer 133 is directly formed on the transition layer 132. The transition layer 132 may be made of titanium or chromium. The openings 135 are defined through the second color layer 133 and the transition layer 132. The first color layer 131 is partially exposed out of the second color layer 133 and the transition layer 132 by the openings 135, thereby providing two different colored regions on the coated article 10.

The first color layer 131, transition layer 132, and the second color layer 133 may be formed by physical vapor deposition, such as magnetron sputtering.

A method for manufacturing the coated article 10 may include: forming the first color layer 131 on the substrate 11 by physical vapor deposition; forming the second color layer 133 on the first color layer 131 by physical vapor deposition, the first and second color layers 131, 133 having different colors from each other; masking portions of the second color layer 133 with a masking material resistant to chemical etching; removing portions of the second color layer 133 not masked by the masking material by immersing the substrate 11 into a chemical solution having no effect on the masking material, thereby forming the openings 135 in the second color layer 133 and exposing potions of the first color layer 131; and removing the masking material.

The physical vapor deposition may be magnetron sputtering.

Under magnetron sputtering conditions, magnetron sputtering the first color layer 131 includes using one or more gases selected from the group consisting of acetylene, oxygen, and nitrogen as reaction gases, applying an electric power to a chromium target to sputter the chromium target material onto the substrate 11 and deposit the first color layer 131. Magnetron sputtering the second color layer 133 includes under magnetron sputtering conditions using one or more gases selected from the group consisting of acetylene, oxygen, and nitrogen as reaction gases, applying an electric power to a titanium target to sputter the titanium target material onto the first color layer 131 and deposit the second color layer 133. Magnetron sputtering the first color layer 131 and the second color layer 133 may be successively carried out in the same magnetron sputtering machine.

The masking material may be an ink and formed on the second color layer 133 by printing. Accordingly, the masking material can be removed by organic solutions. The masking material may also be adhesive paper.

Since the first color layer 131 and the second color layer 133 have different chemical compositions, the chemical solution can be selected to only react with the second color layer 133 and have no effect on the first color layer 131.

In other embodiments, the method may further include forming a transition layer 132 comprising chromium or titanium by physical vapor deposition between the steps of forming the first color layer 131 and forming the second color layer 133. The transition layer 132 may reduce the internal stress between the first color layer 131 and the second color layer 133. When immersing the substrate 11 into the chemical solution, portions of the transition layer 132 corresponding to the openings 135 are also removed by the chemical solution.

The electric power may be provided using any power source for magnetron sputtering, such as intermediate frequency power source.

The magnetron sputtering conditions include: using an inert gas (such as argon) having flow rate of about 150 Standard Cubic Centimeters per Minute (sccm) to about 250 sccm as a sputtering gas; at an sputtering pressure of about 0.3 Pa to about 0.6 Pa; at a sputtering temperature of about 110° C. to about 180° C. The sputtering pressure means an internal absolute pressure of a chamber for implementing a sputtering during the sputtering process. The sputtering temperature means an internal temperature of the chamber for implementing a sputtering during the sputtering process.

A specific example of making the coated article 10 is described as following.

### EXAMPLE

A sample of 316L-type stainless steel substrate was cleaned with alcohol in an ultrasonic cleaner and then placed into a vacuum chamber of the magnetron sputtering machine (not shown). The magnetron sputtering machine further included a rotating bracket and targets inside the vacuum chamber. The rotating bracket rotated the substrate in the chamber relative to the targets. The targets included a pair of chromium targets and a pair of titanium targets.

The vacuum chamber was evacuated to maintain an internal pressure of about 6.0×10⁻³ Pa. The internal temperature of the vacuum chamber was maintained at about 150° C. Argon gas and acetylene were simultaneously fed into the vacuum chamber, with an argon flow rate of about 200 sccm and an acetylene flow rate of about 60 sccm to about 90 sccm. The argon and acetylene gases created a total pressure of about 0.4 Pa inside the vacuum chamber. A bias voltage of about −100 V was applied to the substrate. About 15 kW of power was applied to the chromium targets, depositing a first color layer of chromium carbide on the substrate. The deposition of the first color layer took about 60 minutes. The first color layer was silver.

The chromium target and the acetylene were switched off. About 15 kW of power was applied to the titanium targets, depositing a transition layer consisting of titanium on the first color layer, with other parameters the same as during deposition of the first color layer. The deposition of the transition layer took about 5 minutes.

Acetylene having a flow rate of about 90 sccm to about 150 sccm was fed into the vacuum chamber as the reaction gas. Other parameters were the same as during deposition of the transition layer, depositing a second color layer of titanium carbide on the transition layer. The deposition of the second color layer took about 60 minutes. The second color layer was black.

The titanium targets, the bias voltage, and the acetylene were switched off. When cooled, the substrate with the first and second color layers and the transition layer was removed from the vacuum chamber.

An ink layer resistant to chemical etching was then printed on the second color layer, partially masking the second color layer.

The masked substrate was immersed into a chemical solution, removing portions of the second color layer not covered by the ink layer and corresponding portions of the transition layer to form openings through the second color layer and the transition layer. As thus, portions of the first color layer were exposed though the openings, providing two different colored regions (silver regions and black regions) on the coated article.

The sample created by this embodiment was inspected. Fringes of the second color layer and the transition layer surrounding the openings were sharp, with no burrs or sawteeth.

The method for making the coated article employs only one masking step, thereby ensuring a high locating accuracy for the masking material. A pattern formed by the openings has a high precision.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A coated article, comprising:
a substrate;
a first color layer directly formed on the substrate, the first color layer made of a first metallic material; and
a second color layer directly formed on the first color layer, the second color layer made of a second metallic material, the first and second color layers having different colors, the second color layer having openings, the first color layer partially exposed out of the second color layer by the openings.

2. The coated article as claimed in claim 1, wherein the first metallic material is selected from the group consisting of chromium carbide, chromium nitride, and chromium oxynitride.

3. The coated article as claimed in claim 1, wherein the second metallic material is selected from the group consisting of titanium carbide, titanium nitride, and titanium carbonitride.

4. The coated article as claimed in claim 1, wherein the substrate is made of metal.

5. The coated article as claimed in claim 1, wherein the substrate is made of plastic.

6. A coated article, comprising:
a substrate;
a first color layer directly formed on the substrate, the first color layer made of a first metallic material;
a transition layer directly formed on the first color layer, the transition layer made of chromium or titanium; and
a second color layer directly formed on the transition layer, the second color layer made of a second metallic material;
the first and second color layers having different colors, the second color layer and the transition layer having openings therethrough, the first color layer partially exposed out of the second color layer and the transition layer by the openings.

7. The coated article as claimed in claim 6, wherein the first metallic material is selected from the group consisting of chromium carbide, chromium nitride, and chromium oxynitride.

8. The coated article as claimed in claim 6, wherein the second metallic material is selected from the group consisting of titanium carbide, titanium nitride, and titanium carbonitride.

9. A method for manufacturing a coated article, comprising:
forming a first color layer on the substrate by physical vapor deposition, the first color layer made of a first metallic material;
forming a second color layer on the first color layer by physical vapor deposition, the first and second color layers having different colors, the second color layer made of a second metallic material;
masking portions of the second color layer with a masking material resistant to chemical etching;
removing portions of the second color layer not masked by the masking material by immersing the substrate into a chemical solution having no effect on the masking material, thereby forming openings through the second color layer and exposing potions of the first color layer by the openings; and
removing the masking material.

10. The method of claim 9, wherein the physical vapor deposition process is magnetron sputtering.

11. The method of claim 10, wherein magnetron sputtering the first color layer includes under magnetron sputtering conditions using one or more gases selected from the group consisting of acetylene, oxygen, and nitrogen as reaction gases, applying an electric power to a chromium target to sputter the chromium target material onto the substrate.

12. The method of claim 11, wherein the magnetron sputtering conditions include using an inert gas having a flow rate of about 150 sccm to about 250 sccm as a sputtering gas; conducting the magnetron sputtering at an sputtering pressure of about 0.3 Pa to about 0.6 Pa and at a sputtering temperature of about 110° C. to about 180° C.

13. The method of claim 11, wherein magnetron sputtering the second color layer includes under magnetron sputtering conditions using one or more gases selected from the group consisting of acetylene, oxygen, and nitrogen as reaction gases, applying an electric power to a titanium target to sputter the titanium target material onto the first color layer.

14. The method of claim 13, wherein the magnetron sputtering conditions include using an inert gas having a flow rate of about 150 sccm to about 250 sccm as a sputtering gas; conducting the magnetron sputtering at an sputtering pressure of about 0.3 Pa to about 0.6 Pa and at a sputtering temperature of about 110° C. to about 180° C.

15. The method of claim 10, wherein the steps of magnetron sputtering the first color layer and magnetron sputtering the second color layer are successively carried out in the same magnetron sputtering machine.

16. The method of claim 9, wherein the masking material is ink and formed on the second color layer by printing.

17. The method of claim 9, further comprising forming a transition layer consisting of chromium or titanium by physical vapor deposition, between the steps of forming the first color layer and forming the second color layer.

18. The method of claim 17, wherein during immersing the substrate into the chemical solution, portions of the transition layer corresponding to the openings are also removed by the chemical solution.
